(19) United States
(12) Patent Application Publication
(10) Pub. No.: US 2024/0090189 A1
(43) Pub. Date: Mar. 14, 2024

(54) LAMINATING DEVICE AND LAMINATING METHOD FOR ELECTRONIC DEVICE

(71) Applicant: Zhengzhou Yilian International Trade Co., LTD, Zhenghou (CN)

(72) Inventor: Ke Xue, Zhengzhou (CN)

(21) Appl. No.: 17/970,129

(22) Filed: Oct. 20, 2022

(30) Foreign Application Priority Data
Sep. 14, 2022 (CN) 2022111162589

(51) Int. Cl. H05K 13/04; H05K 13/00

(52) U.S. Cl. CPC H05K 13/04; H05K 13/0015; G06F 1/1656

(57) ABSTRACT

A protector installation device for an electronic device includes a shell and a protector. The shell is provided with an accommodating space, a first mounting end face, and a second mounting end face. The accommodating space is communicated to the second mounting end face of the shell from the first mounting end face of the shell, so that the accommodating space forms a placement opening in the first mounting end face, and the accommodating space forms a mounting opening in the second mounting end face. The placement opening is used for allowing the electronic device to be put into the accommodating space. The protector is arranged on the second mounting end face; and the protector blocks the mounting opening, so that the protector is fitted to a screen of the electronic device in the accommodating space via the mounting opening.

### CROSS-REFERENCE TO RELATED APPLICATIONS

The application claims priority of Chinese patent application 202211116258.9, filed on Sep. 14, 2022, which is incorporated herein by reference in its entireties.

### TECHNICAL FIELD

The present disclosure relates to the field of screen protector lamination for electronic devices, in particular to, a protector installation device and a protector installation method for an electronic device.

### BACKGROUND

With the continuous progress and development of science and technology, electronic devices such as a mobile phone and a tablet computer have been widely used in daily life. However, during the use of an electronic device, the screen is easily scratched. Once there is a scratch, the display effect and aesthetics of the screen of the electronic device will be greatly affected. Therefore, in order to protect the screen and prevent scratches, most users will laminate a screen protector on the screen of the electronic device to protect the screen during use. At present, screen protectors are manually laminated to electronic devices in most cases. In order to facilitate the lamination of the screen protectors to the electronic devices, various auxiliary protector installation tools have appeared on the market. However, the existing auxiliary protector installation tools are cumbersome to use, and have low protector installation efficiency and poor positioning effect. The electronic device protector is easily obliquely laminated. Meanwhile, air easily exists between the electronic device protector and the screen, which affects the display effect of the electronic device.

### SUMMARY

In order to overcome the shortcomings in the prior art, the present disclosure provides a protector installation device and a protector installation method for an electronic device, which are “convenient to operate, accurate in positioning and high in protector installation efficiency, and it is hard for air to remain.”

The present disclosure adopts the following technical solution: a protector installation device for an electronic device, including a shell and a protector, wherein the shell is provided with an accommodating space, a first mounting end face, and a second mounting end face; the accommodating space is communicated to the second mounting end face of the shell from the first mounting end face of the shell, so that the accommodating space forms a placement opening in the first mounting end face, and the accommodating space forms a mounting opening in the second mounting end face; the placement opening is used for allowing the electronic device to be put into the accommodating space; the protector is arranged on the second mounting end face; and the protector blocks the mounting opening, so that the protector is fitted to a screen of the electronic device in the accommodating space via the mounting opening.

Further, the protector includes a first unit protector and a second unit protector which are stacked; the first unit protector is connected to the second mounting end face; the second unit protector is stacked on one side of the first unit protector facing to the mounting opening; and the second unit protector falls into the mounting opening.

Further, an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; and the upper positioning hole sleeves the upper positioning block, and the lower positioning hole sleeves the lower positioning block, so that the first unit protector is connected to the second mounting end face.

Further, the shell further includes a fixing member; the fixing member is provided with a limiting slot for plugging the upper positioning block; and the upper positioning block threaded into the upper positioning hole is plugged into the limiting slot, so that the upper edge portion is fixed between the second mounting end face and the fixing member.

Further, the protector further includes a third unit protector; the third unit protector is stacked on one side of the second unit protector facing to the mounting opening; and the third unit protector falls into the mounting opening.

Further, a lift-up portion extends out of a top of the third unit protector; the mounting opening is provided with an accommodating slot used for accommodating the lift-up portion; and the lift-up portion is arranged in the accommodating slot when the protector blocks the mounting opening.

The present disclosure also adopts the following technical solution: a protector installation method for an electronic device, including the following steps:
providing the protector installation device for an electronic device, wherein the protector includes a first unit protector and a second unit protector which are stacked; the first unit protector is connected to the second mounting end face; the second unit protector is stacked on one side of the first unit protector facing to the mounting opening; the second unit protector falls into the mounting opening;
enabling a screen of the electronic device to face to the second unit protector at the second mounting end face, and putting the electronic device into the accommodating space via the placement opening;
applying an acting force, which faces to the screen of the electronic device, to the bottom of the first unit protector from a side where the second mounting end face is located, so as to attach the bottom of the second unit protector to the screen of the electronic device;
lifting the first unit protector off the second unit protector from the bottom of the first unit protector; and when the first unit protector is lifted off the second unit protector, applying, by the bent first unit protector, an acting force, which faces to the screen of the electronic device, to the second unit protector, so as to discharge air between the second unit protector and the screen of the electronic device and attach the second unit protector to the screen of the electronic device.

Further, the protector further includes a third unit protector; the third unit protector is stacked on one side of the second unit protector facing to the mounting opening; the third unit protector falls into the mounting opening; a lift-up portion extends out of a top of the third unit protector; the mounting opening is provided with an accommodating slot used for accommodating the lift-up portion; the lift-up portion is arranged in the accommodating slot when the protector blocks the mounting opening; the step of enabling a screen of the electronic device to face to the second unit protector at the second mounting end face, and putting the electronic device into the accommodating space via the placement opening includes: lifting the third unit protector off the second unit protector through the lift-up portion; and putting the electronic device into the accommodating space.

Further, the step of applying an acting force, which faces to the screen of the electronic device, to the bottom of the first unit protector from a side where the second mounting end face is located, so as to attach the bottom of the second unit protector to the screen of the electronic device includes:
applying the acting force, which faces to the screen of the electronic device, to the bottom of the first unit protector from one side to the other side; and
discharging the air between the bottom of the second unit protector and the screen of the electronic device, so as to cling the bottom of the second unit protector to the bottom of the screen of the electronic device.

Further, an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; the upper positioning hole sleeves the upper positioning block, and the lower positioning hole sleeves the lower positioning block, so that the first unit protector is connected to the second mounting end face; the shell further includes a fixing member; the fixing member is provided with a limiting slot for plugging the upper positioning block; the upper positioning block threaded into the upper positioning hole is plugged into the limiting slot, so that the upper edge portion is fixed between the second mounting end face and the fixing member;
the step of lifting the first unit protector off the second unit protector from the bottom of the first unit protector; and when the first unit protector is lifted off the second unit protector, applying, by the bent first unit protector, an acting force, which faces to the screen of the electronic device, to the second unit protector, so as to discharge air between the second unit protector and the screen of the electronic device and attach the second unit protector to the screen of the electronic device includes:
grabbing the lower edge portion on the side where the second mounting end face is located;
lifting the first unit protector off the second unit protector from the bottom to the top through the lower edge portion;
bending the lifted first unit protector relative to the non-lifted first unit protector to apply the acting force, which faces to the screen of the electronic device, to the second unit protector; and
when the first unit protector is lifted off the second unit protector from the bottom to the top, under the acting force of the first unit protector, discharging the air between the second unit protector and the screen of the electronic device from bottom to top, so as to attach the second unit protector to the screen of the electronic device.

The present disclosure further adopts the following technical solution: a protector installation device for an electronic device, including a shell and a transparent protection film, the shell including an accommodating space, a placement opening communicated with the accommodating space, and a mounting opening communicated with the accommodating space and facing the placement opening, the placement opening configured for allowing the electronic device to be put into the accommodating space, the transparent protection film disposed at the mounting opening, so that the transparent protection film is able to be attached to a screen of the electronic device in the accommodating space via the mounting opening.

Further, the shell includes a first mounting end face having the placement opening and a second mounting end face having the second mounting end face; the transparent protection film includes a first unit protector and a second unit protector which are stacked; the first unit protector is connected to the second mounting end face; the second unit protector is stacked on one side of the first unit protector facing to the mounting opening; and the second unit protector falls into the mounting opening.

Further, an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; and the upper positioning hole sleeves the upper positioning block, and the lower positioning hole sleeves the lower positioning block, so that the first unit protector is connected to the second mounting end face.

Further, the shell further includes a fixing member; the fixing member is provided with a limiting slot for plugging the upper positioning block; and the upper positioning block threaded into the upper positioning hole is plugged into the limiting slot, so that the upper edge portion is fixed between the second mounting end face and the fixing member.

Further, the transparent protection film further includes a third unit protector; the third unit protector is stacked on one side of the second unit protector facing to the mounting opening; and the third unit protector falls into the mounting opening.

Further, a lift-up portion extends out of a top of the third unit protector; the mounting opening is provided with an accommodating slot used for accommodating the lift-up portion; and the lift-up portion is arranged in the accommodating slot when the transparent protection film blocks the mounting opening.

In the present disclosure, by the arrangement of the accommodating space and the mounting opening, during protector installation, the electronic device is placed in the accommodating space, which can position the screen of the electronic device and the mounting opening; at this time, the mounting opening will face directly to the screen of the electronic device, and a user can apply an acting force, which faces to the screen of the electronic device, to the protector from one side of the second mounting end face; and the protector (such as a transparent protection film) will be clung to the screen of the electronic device via the mounting opening. The operation is convenient; the positioning is accurate; and the protector installation efficiency is high.

In this embodiment, the protector includes a first unit protector and a second unit protector which are stacked; the first unit protector is connected to the second mounting end face; the second unit protector is stacked on one side of the first unit protector facing to the mounting opening; and the second unit protector falls into the mounting opening. It can be understood, each of the first unit protector and the second unit protector can be a transparent protection layer.

By the above-mentioned structural arrangement, the second unit protector is fixed at the mounting opening through the first unit protector. During protector installation, the electronic device is put in the accommodating space, and an acting force which faces to the screen of the electronic device is then applied to the first unit protector from one side of the second mounting end face, so that the second unit protector is attached to the screen of the electronic device via the mounting opening by the first unit protector under this acting force; and the first unit protector is lifted off on one side of the second mounting end face, so as to complete the lamination. The operation is simple, and the positioning is convenient.

### BRIEF DESCRIPTION OF THE DRAWINGS

FIG. 1 illustrates a three-dimensional diagram of a shell (seen from a second mounting end face) of a protector installation device;

FIG. 2 illustrates a three-dimensional diagram of a shell (seen from a first mounting end face) of a protector installation device;

FIG. 3 illustrates a three-dimensional diagram of a protector installation device (seen from a second mounting end face);

FIG. 4 illustrates an exploded diagram of a protector installation device (seen from a second mounting end face);

FIG. 5 is a partially enlarged diagram of part A;

FIG. 6 is a partially enlarged diagram of part B;

FIG. 7 illustrates an exploded diagram of a protector installation device (seen from a first mounting end face);

FIG. 8 is a partially enlarged diagram of part C;

FIG. 9 illustrates a sectional view of a protector installation device;

FIG. 10 is a partially enlarged diagram of part D;

FIG. 11 illustrates a diagram of a use state of a protector installation device (seen from a first mounting end face);

FIG. 12 illustrates a diagram of a use state of a protector installation device (seen from a second mounting end face);

FIG. 13 illustrates a diagram of a use state in which a first unit protector of the protector installation device is lifted off a second unit protector (seen from a second mounting end face);

FIG. 14 illustrates a flow chart of a protector installation method of the present disclosure of Embodiment II;

FIG. 15 illustrates a flow chart of step S11;

FIG. 16 illustrates a flow chart of step S13 and step S14;

FIG. 17 illustrates a flow chart of a protector installation method of the present disclosure of Embodiment III;

FIG. 18 illustrates a flow chart of step S21;

FIG. 19 illustrates a flow chart of step S22; and

FIG. 20 illustrates a flow chart of step S23.

### DETAILED DESCRIPTION OF THE EMBODIMENTS

### Embodiment I

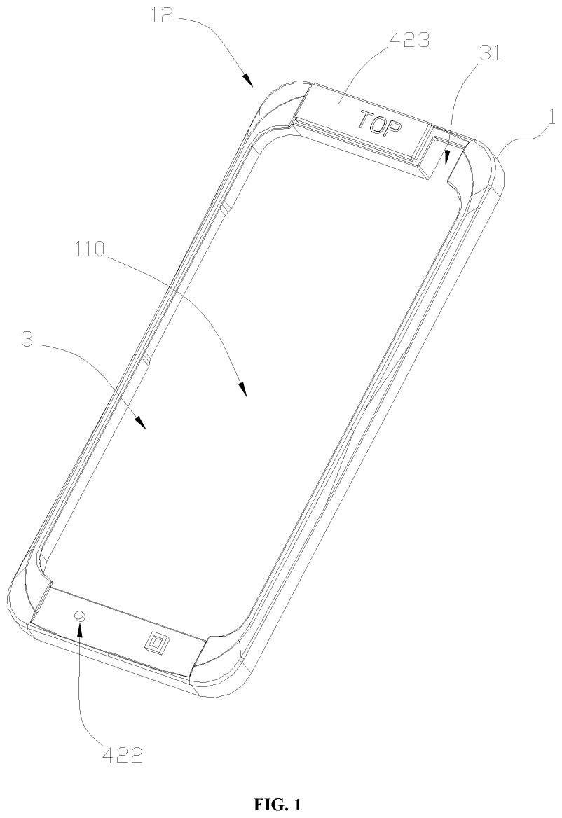

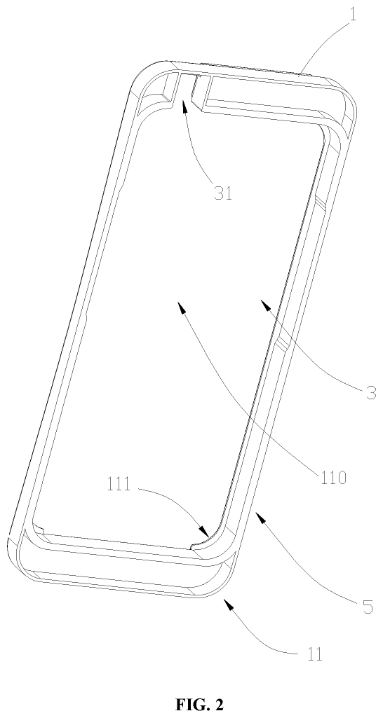

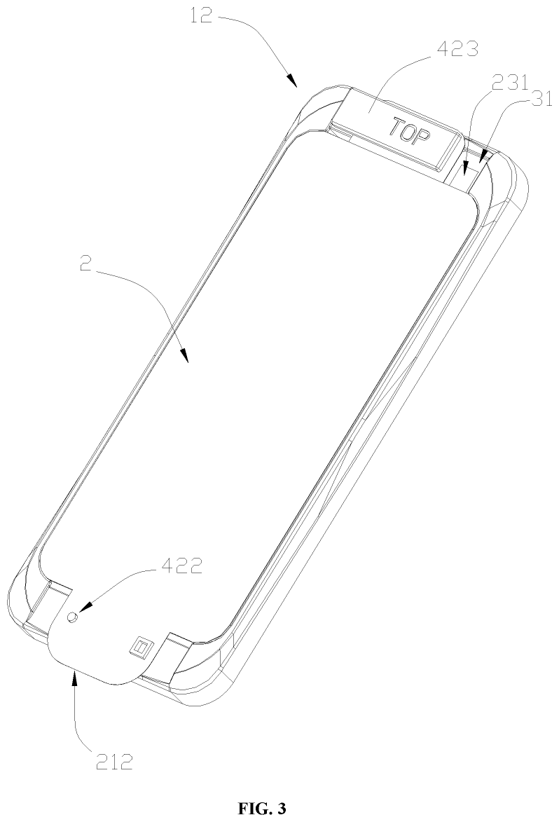

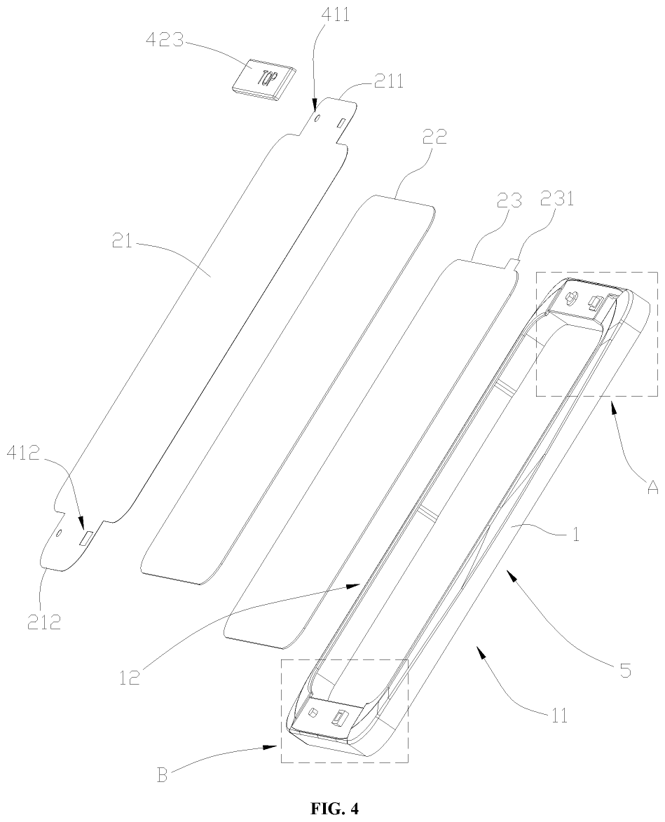

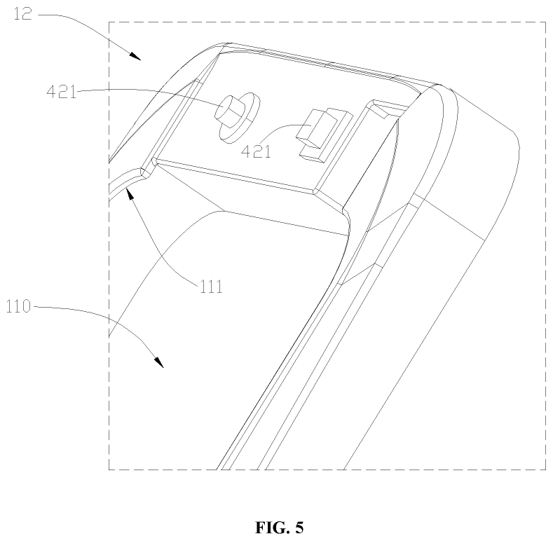

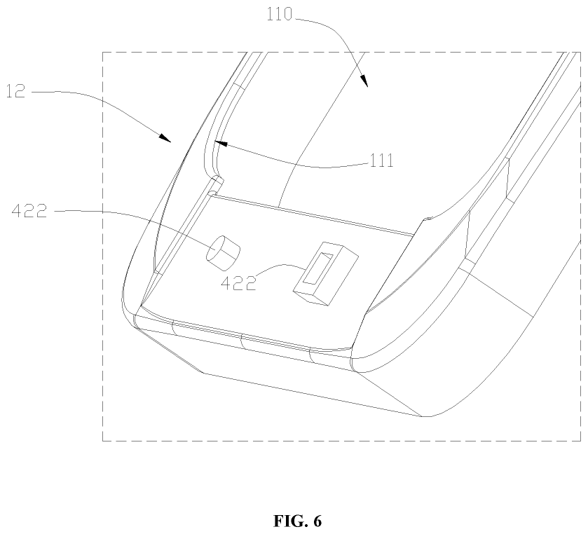

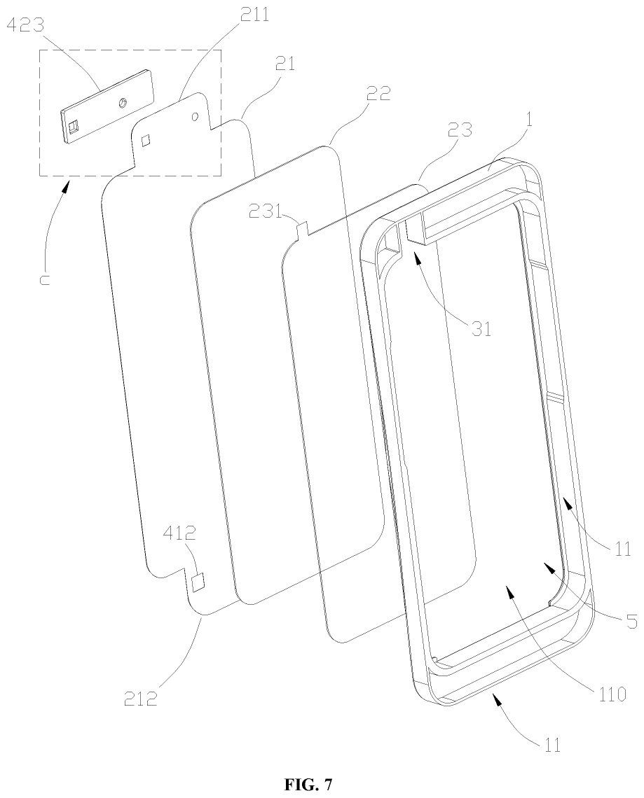

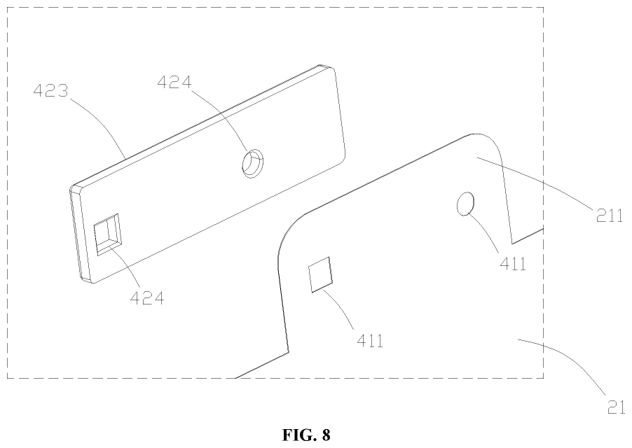

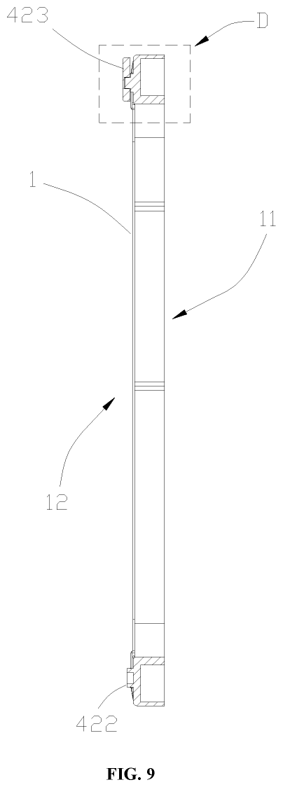

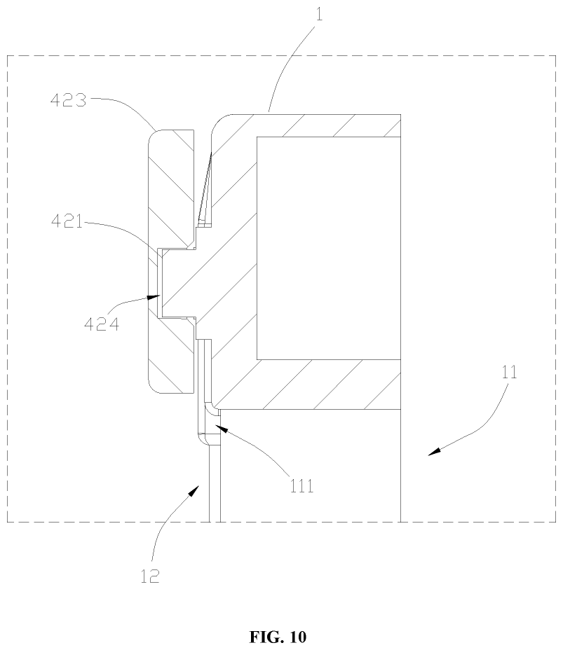

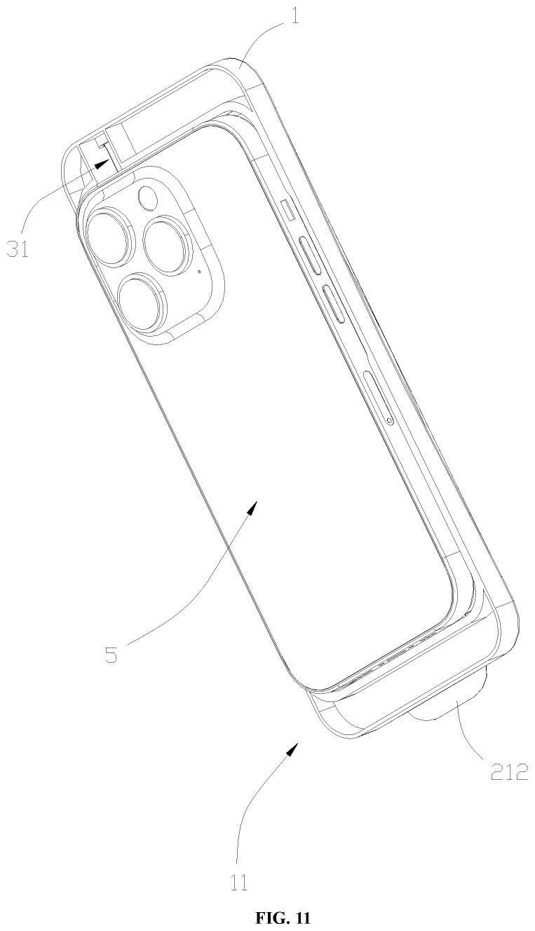

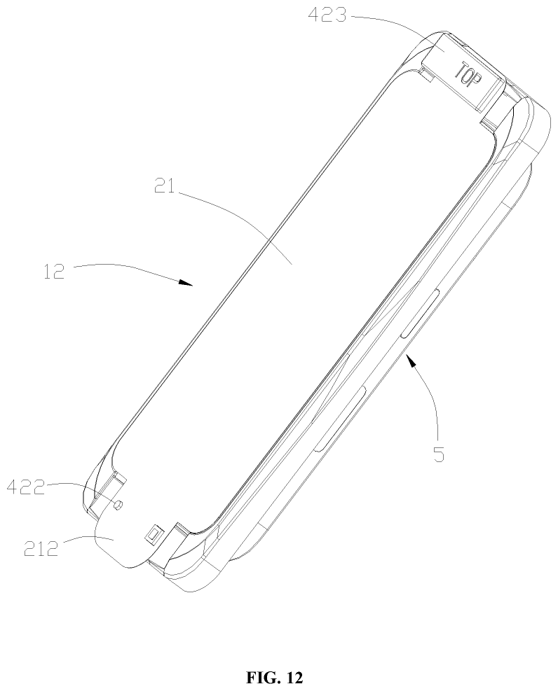

As shown in FIG. 1 to FIG. 13, a protector installation device for an electronic device in this embodiment includes a shell 1 and a protector 2; the shell 1 is provided with an accommodating space 110, a first mounting end face 11, and a second mounting end face 12; the accommodating space 110 runs through the second mounting end face 12 of the shell 1 from the first mounting end face 11 of the shell 1, so that the accommodating space 110 forms a placement opening 5 on the first mounting end face, and the accommodating space 110 forms a mounting opening 3 on the second mounting end face 12; the electronic device is put into the accommodating space 110 through the placement opening 5; and the protector 2 is arranged on the second mounting end face 12, and the protector 2 blocks the mounting opening 3, so that the protector 2 may be attached to a screen of the electronic device in the accommodating space 110 via the mounting opening 3. In this embodiment, the accommodating space 110 may also be provided with a stop wall 111 that extends inwards to fix the electronic device. Specifically, when the electronic device is placed in the accommodating space 110, the electronic device will abut against the stop wall 111, so as to achieve fixing of the electronic device. It can be understood, the protector 2 can be a transparent protection film.

In the present disclosure, by the arrangement of the accommodating space 110 and the mounting opening 3, during protector installation, the electronic device is placed in the accommodating space 110, which can position the screen of the electronic device and the mounting opening; at this time, the mounting opening 3 will face directly to the screen of the electronic device, and a user can apply an acting force, which faces to the screen of the electronic device, to the protector 2 from one side of the second mounting end face 12; and the protector 2 will be clung to the screen of the electronic device via the mounting opening 3. The operation is convenient; the positioning is accurate; and the protector installation efficiency is high.

In this embodiment, the protector 2 includes a first unit protector 21 and a second unit protector 22 which are stacked; the first unit protector 21 is connected to the second mounting end face 12; the second unit protector 22 is stacked on one side of the first unit protector 21 facing to the mounting opening 3; and the second unit protector 22 falls into the mounting opening 3. It can be understood, each of the first unit protector 21 and the second unit protector 22 can be a transparent protection layer.

By the above-mentioned structural arrangement, the second unit protector 22 is fixed at the mounting opening 3 through the first unit protector 21. During protector installation, the electronic device is put in the accommodating space 110, and an acting force which faces to the screen of the electronic device is then applied to the first unit protector 21 from one side of the second mounting end face 12, so that the second unit protector 22 is attached to the screen of the electronic device via the mounting opening 3 by the first unit protector 21 under this acting force; and the first unit protector 21 is lifted off on one side of the second mounting end face 12, so as to complete the lamination. The operation is simple, and the positioning is convenient.

An upper edge portion 211 and a lower edge portion 212 respectively extend out of a top and bottom of the first unit protector 21; the upper edge portion 211 is provided with an upper positioning hole 411; the lower edge portion 212 is provided with a lower positioning hole 412; a top and bottom of the second mounting end face are respectively provided with an upper positioning block 421 and a lower positioning block 422; and the upper positioning hole 411 sleeves the upper positioning block 421, and the lower positioning hole 412 sleeves the lower positioning block 422, so that the first unit protector 21 is connected to the second mounting end face 12.

By the above-mentioned structural arrangement, the upper positioning hole 411 sleeves the upper positioning block 421, and the lower positioning hole 412 sleeves the lower positioning block 422, so as to prevent the first unit protector 21 from moving relative to the second mounting end face 12 during protector installation, thus preventing the second unit protector 22 from shifting relative to the screen of the electronic device, and more accurately attaching the second unit protector 22 to the screen of the electronic device; and when the first unit protector 21 needs to be lifted away, the lower edge portion 212 is grabbed to lift the first unit protector 21 off the second unit protector 22 from bottom to top. Preferably, the lower edge portion 212 is further provided with an adhesion member which is used to achieve adhered connection between the lower edge portion 212 and the second mounting end face 12.

The shell 1 further includes a fixing member 423; the fixing member 423 is provided with a limiting slot 424 for plugging the upper positioning block 421; and the upper positioning block 421 threaded into the upper positioning hole 411 is plugged into the limiting slot 424, so that the upper edge portion 211 is fixed between the second mounting end face 12 and the fixing member 423.

By the above-mentioned structural arrangement, the upper edge portion 211 is fixed between the second mounting end face 12 and the fixing member 423 through the fixing member 423; and when the first unit protector 21 is lifted off the second unit protector 22 from bottom to top, the fixed upper edge portion can effectively prevent the first unit protector 21 from moving relative to the second unit protector. As the first unit protector 21 is lifted off the second unit protector 22 from bottom to top, the first unit protector 21 will apply an acting force, which faces to the screen of the electronic device, to the second unit protector, so as to attach the second unit protector on the screen of the electronic device and discharge air between the second unit protector and the screen of the electronic device at the same time. Specifically, As the first unit protector 21 is lifted off the second unit protector 22 from bottom to top, the second unit protector 22 will be synchronously attached to the screen of the electronic device from bottom to top, so that the operation is convenient, and the design is ingenious. It should be noted that when the first unit protector 21 is lifted off the second unit protector 22, an adhesion force between the first unit protector 21 and the second unit protector 22 will affect the air discharging effect of the second unit protector 22. Either an extremely high adhesion force or an extremely low adhesion force will affect the smoothness of discharging the air. As a preference, a force for lifting the first unit protector 21 off the second unit protector 22 in this embodiment is between 20 g and 30 g. By the above-mentioned arrangement, when the first unit protector 21 is lifted off the second unit protector 22, the air between the second unit protector 22 and the screen of the electronic device is discharged more smoothly.

The protector 2 of this embodiment further includes a third unit protector 23; the third unit protector 23 is stacked on one side of the second unit protector 22 facing to the mounting opening 3; and the third unit protector 23 falls into the mounting opening 3. The third unit protector 23 and the aforementioned first unit protector are used for protecting the second unit protector 22. The third unit protector 23 can be a transparent protection layer.

Before protector installation, the third unit protector 23 can be removed from the accommodating space 110 of the first mounting end face 11. In this embodiment, in order to facilitate the third unit protector 23 to be lifted off, as a preference, a lift-up portion 231 that outwards extends is arranged at a top edge of the third unit protector 23; the mounting opening 3 is provided with an accommodating slot 31 matched with the lift-up portion 231 and used for accommodating the lift-up portion 231; and the lift-up portion 231 is arranged in the accommodating slot 31 when the protector 2 blocks the mounting opening 3. Specifically, the lift-up portion 231 of this embodiment is a lug arranged at the top of the third unit protector 23. When the third unit protector 23 needs to be removed, the lift-up portion 231 in the accommodating slot 31 may be grabbed, and an acting force away from the second unit protector 22 is then applied to the lift-up portion 231 to lift the third unit protector 23 off the second unit protector 22.

By the above-mentioned structural arrangement, during protector installation, the third unit protector 23 can be removed from the second unit protector 22 through the lift-up portion 231, and the electronic device is put into the accommodating space 110 in a direction where the screen faces to the mounting opening 3, so that the screen of the electronic device just faces to the second unit protector 22. At this time, the acting force which faces to the screen of the electronic device is applied to the first unit protector 21 from one side of the second mounting end face 12, so as to cling the second unit protector 22 to the screen of the electronic device; the first unit protector 21 is removed from one side of the second mounting end face 12, so as to achieve convenient and accurate mounting of the second unit protector 22; the protector installation device is convenient to use; and the error-tolerant rate of mounting and the mounting efficiency are greatly improved.

### Embodiment II

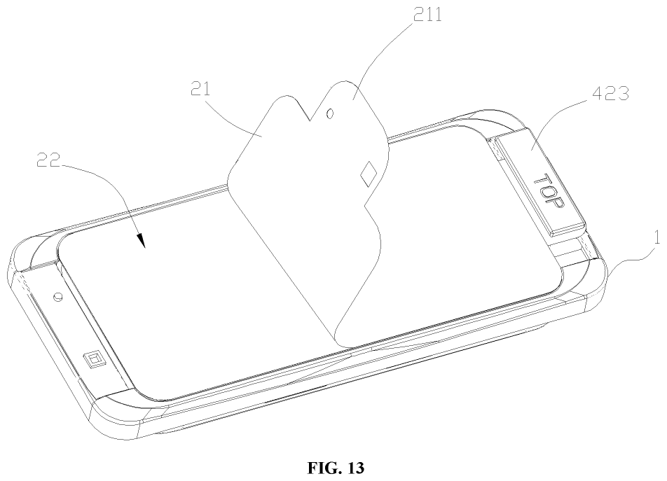

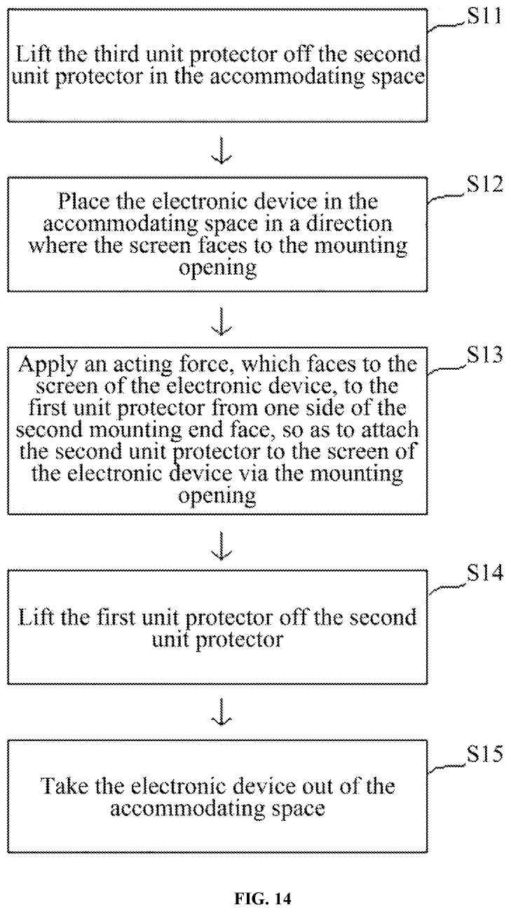

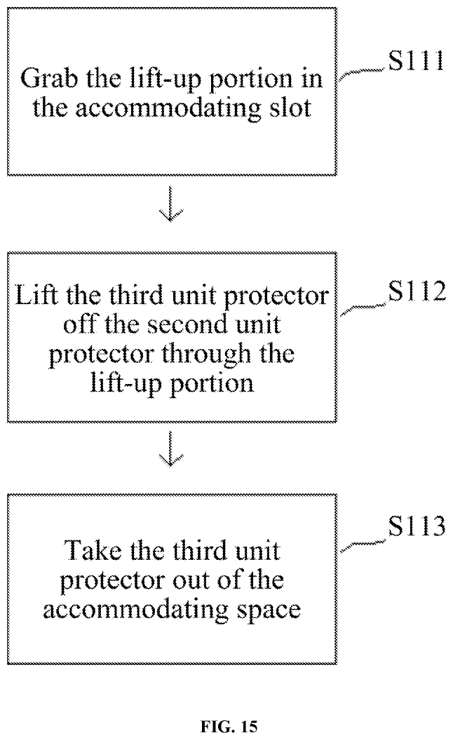

As shown in FIG. 13 to FIG. 16, this embodiment provides a protector installation method applied to the protector installation device for an electronic device in Embodiment I. Specifically, the method includes the following steps:
S11: the third unit protector 23 is lifted off the second unit protector 22 in the accommodating space 110;
S12: the electronic device is placed in the accommodating space 110 in a direction where the screen faces to the mounting opening 3;
S13: an acting force which faces to the screen of the electronic device is applied to the first unit protector 21 from one side of the second mounting end face 12, so as to attach the second unit protector 22 to the screen of the electronic device via the mounting opening 3;
S14: the first unit protector 21 is lifted off the second unit protector 22; and
S15: the electronic device is taken out of the accommodating space 110.

By the above-mentioned steps, during protector installation, the electronic device, such as a mobile phone 5, can be placed on an operating platform, such as a tabletop; the protector installation device for an electronic device in Embodiment I is taken out; the third unit protector 23 is lifted off the second unit protector 22 in the accommodating space 110; the accommodating space 110 of the first mounting end face 11 is aligned with the screen of the mobile phone 5 and covers mobile phone 5; when the electronic device is placed in the accommodating space 110, the second unit protector 22 at the mounting opening 3 is just aligned with the screen; at this time, the acting force which faces to the screen of the electronic device is applied to the first unit protector 21 from the second mounting end face 12; at this time, the first unit protector 21 and the second unit protector will pass through the mounting opening 3 and be continuously close to the screen under the action of the above-mentioned acting force until the second unit protector 22 is in contact with the screen; the first unit protector 21 is then lifted off the second unit protector 22 from the second mounting end face 12, so as to cling the second unit protector 22 to the screen of the electronic device; and finally, the mobile phone 5 is taken out of the accommodating space 110, thus completing protector installation a protector to the mobile phone 5. It should be noted that the protector installation device and the protector installation method for an electronic device of the present disclosure are also applicable to other electronic devices, such as a tablet computer and an MP4.

Step S11 further includes:
S111: the lift-up portion 231 is grabbed in the accommodating slot 31;
S112: the third unit protector 23 is lifted off the second unit protector 22 through the lift-up portion 231; and
S113: the third unit protector 23 is taken out of the accommodating space 110.

By the above-mentioned step, a user can conveniently lift the third unit protector 23 off the second unit protector 22 by grabbing the lift-up portion 231.

Step S13 further includes:
S131: the acting force which faces to the screen of the electronic device is applied to the bottom edge of the first unit protector 21 from one side to another side, so as to cling the bottom edge of the second unit protector 22 to the screen of the electronic device; and
S132: if there is air between the bottom edge of the second unit protector 22 and the screen of the electronic device, the bottom edge of the first unit protector 21 is pressed to discharge the air between the bottom edge of the second unit protector 22 and the screen of the electronic device.

If there is no air between the bottom edge of the second unit protector 22 and the screen of the electronic device, step S132 can be omitted; and if there is air between the bottom edge of the second unit protector 22 and the screen of the electronic device, the bottom edge of the first unit protector 21 needs to be pressed to discharge the air between the bottom edge of the second unit protector 22 and the screen of the electronic device.

Step S14 further includes:
S141: the lower edge portion 212 is grabbed from the second mounting end face 12;
S142: an acting force which faces to the top of the first unit protector 21 and is away from the second unit protector is applied to the lower edge portion 212; and
S143: the lifted first unit protector 21 applies an acting force which faces to the screen of the electronic device to the second unit protector 22, so as to attach the second unit protector 22 to the screen of the electronic device from bottom to top.

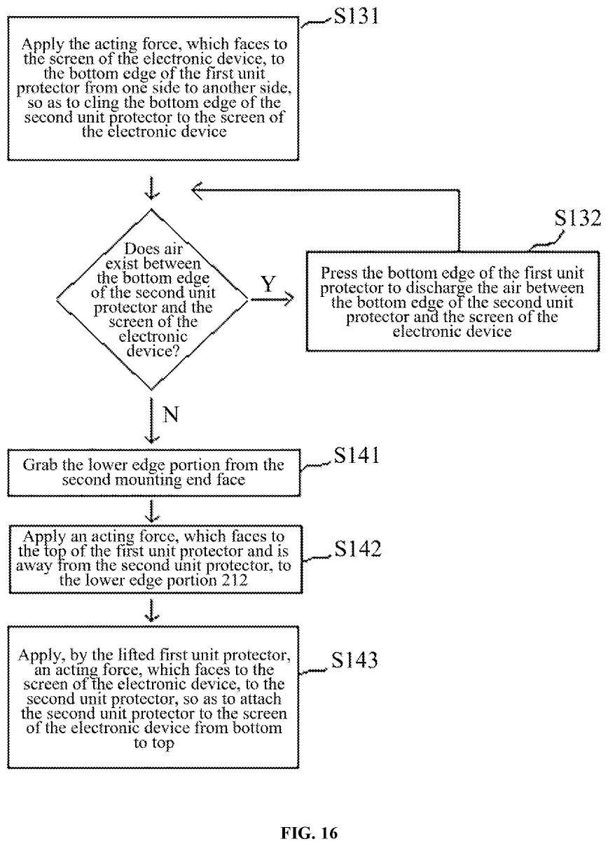

As shown in FIG. 16, by the above-mentioned steps, when the electronic device is placed in the accommodating space 110, the user facing the second mounting end face 12 can press the bottom edge of the first unit protector 21 with a finger. Specifically, the bottom edge of the first unit protector 21 is pressed from one side to the other side, so as to cling the bottom edge of the first unit protector 21 to the bottom edge of the screen of the electronic device, and the user checks whether there is air; if there is air, the above pressing step can be repeated to discharge all the air; after the above-mentioned step is completed, the lower edge portion 212 is then grabbed, and the acting force which faces to the top of the first unit protector 21 and is away from the second unit protector is applied to the lower edge portion 212; under this acting force, the lower edge portion 212 will overcome an adhesion force of the adhesion member to the lower edge portion 212 and the second mounting end face 12, so as to separate the lower edge portion 212 from the second mounting end face 12 and further from the second unit protector 22; and when the first unit protector 21 is separated from the second unit protector 22, the first unit protector 21 is bent under the stress and deforms. As shown in FIG. 13, the first unit protector 21 that is bent to deform generates an elastic force acting on the second unit protector 22, so as to apply the acting force which faces to the screen of the electronic device to the second unit protector 22. As the first unit protector 21 is lifted off the second unit protector 22 from bottom to top, the first unit protector 21 will apply the acting force, which faces to the screen of the electronic device, to the second unit protector 22, so as to attach the second unit protector 22 to the screen of the electronic device and also discharge the air between the second unit protector and the screen of the electronic device. Specifically, as the first unit protector 21 is lifted off the second unit protector 22 from bottom to top, the second unit protector 22 will be synchronously attached to the screen of the electronic device from bottom to top. The operation is convenient, and the design is ingenious. The following technical problem is solved: air easily exists between the protector and the screen in the traditional protector installation process, which affects the display effect of the screen. The practicability is high.

### Embodiment III

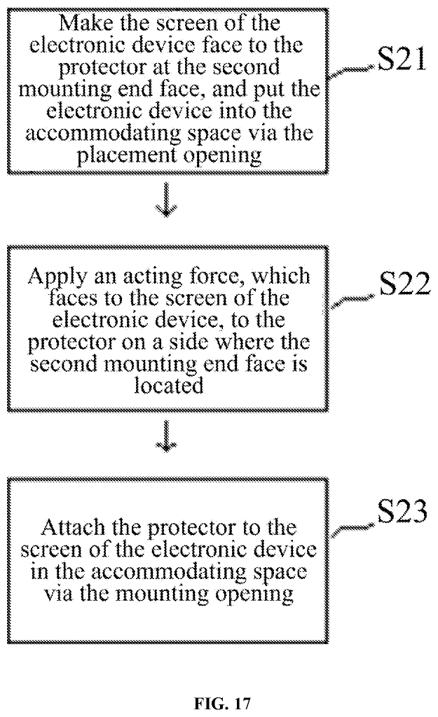

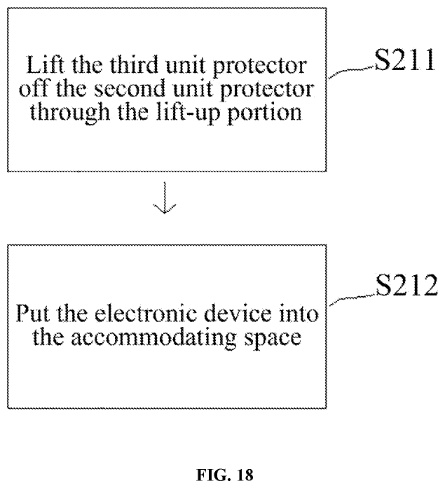

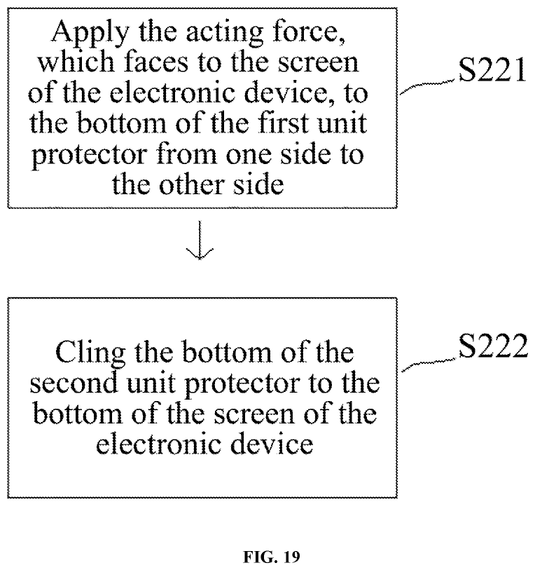

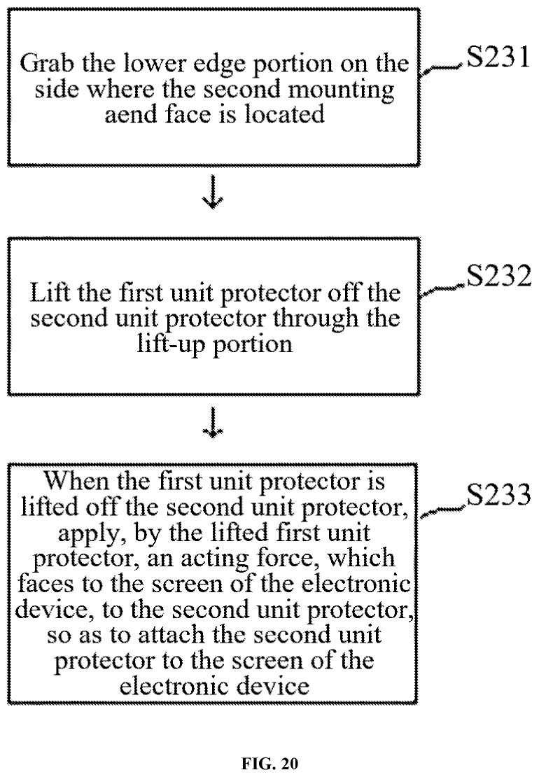

As shown in FIG. 17 to FIG. 20 and FIG. 13, this embodiment provides a protector installation method applied to the protector installation device for an electronic device in Embodiment I. Specifically, the method includes the following steps:
S21: the screen of the electronic device is made to face to the protector 2 at the second mounting end face 12, and the electronic device is put into the accommodating space 110 via the placement opening 5;
S22: an acting force which faces to the screen of the electronic device is applied to the protector 2 on a side where the second mounting end face 12 is located; and
S23: the protector 2 is attached to the screen of the electronic device in the accommodating space 110 via the mounting opening 3.

By the above-mentioned steps, during protector installation, the electronic device, such as a mobile phone 5, can be placed on an operating platform, such as a tabletop; the protector installation device for an electronic device in Embodiment I is taken out; the accommodating space 110 of the first mounting end face 11 is aligned with the screen of the mobile phone 5 and covers mobile phone 5; when the electronic device is placed in the accommodating space 110, the second unit protector 22 at the mounting opening 3 is just aligned with the screen; at this time, the acting force which faces to the screen of the electronic device is applied to the protector 2 from one side of the second mounting end face 12; and at this time, the protector will be continuously close to the screen via the mounting opening 3 until it is attached to the screen, so as to attach 2 to the screen of the mobile phone 5. It should be noted that the protector installation device and the protector installation method for an electronic device of the present disclosure are also applicable to other electronic devices, such as a tablet computer and an MP4.

Step S21 includes:
S211: the third unit protector 23 is lifted off the second unit protector 22 through the lift-up portion 231; and
S212: the electronic device is put into the accommodating space 110.

Step S22 includes:
S221: the acting force which faces to the screen of the electronic device is applied to the bottom of the first unit protector 21 from one side to the other side; and
S222: the bottom of the second unit protector 22 is clung to the bottom of the screen of the electronic device.

Step S23 includes:
S231: the lower edge portion 212 is grabbed on the side where the second mounting end face 12 is located;
S232: the first unit protector 21 is lifted off the second unit protector 22 through the lift-up portion 212; and
S233: when the first unit protector 21 is lifted off the second unit protector 22, the lifted first unit protector 21 applies an acting force which faces to the screen of the electronic device to the second unit protector 22, so as to attach the second unit protector 22 to the screen of the electronic device.

By the above-mentioned steps, the user can conveniently lift the third unit protector 23 off the second unit protector 22 through the lift-up portion 231; the accommodating space 110 of the first mounting end face 11 is aligned with the screen of the mobile phone 5 and covers the mobile phone 5; the bottom edge of the first unit protector 21 is pressed from one side to the other side on one side of the second mounting end face 12, so as to cling the bottom edge o the first unit protector 21 to the bottom edge of the screen of the electronic device, and the user checks whether there is air; if there is air, the above pressing step can be repeated to discharge all the air; after the above-mentioned step is completed, the lower edge portion 212 is then grabbed, and the acting force which faces to the top of the first unit protector 21 and is away from the second unit protector is applied to the lower edge portion 212, so as to separate the first unit protector 21 from the second unit protector 22; and when the first unit protector 21 is separated from the second unit protector 22, the first unit protector 21 is bent under the stress and deforms. As shown in FIG. 13, the first unit protector 21 that is bent to deform generates an elastic force acting on the second unit protector 22, so as to apply the acting force which faces to the screen of the electronic device to the second unit protector 22. As the first unit protector 21 is lifted off the second unit protector 22 from bottom to top, the first unit protector 21 will apply the acting force, which faces to the screen of the electronic device, to the second unit protector 22, so as to attach the second unit protector 22 to the screen of the electronic device and also discharge the air between the second unit protector 22 and the screen of the electronic device. Specifically, as the first unit protector 21 is lifted off the second unit protector 22 from bottom to top, the second unit protector 22 will be synchronously attached to the screen of the electronic device from bottom to top. The operation is convenient, and the design is ingenious. The following technical problem is solved: air easily exists between the protector and the screen in the traditional protector installation process, which affects the display effect of the screen. The practicability is high.

What is claimed is:

1. A protector installation device for an electronic device, comprising a shell and a protector, wherein the shell is provided with an accommodating space, a first mounting end face, and a second mounting end face; the accommodating space is communicated to the second mounting end face of the shell from the first mounting end face of the shell, so that the accommodating space forms a placement opening in the first mounting end face, and the accommodating space forms a mounting opening in the second mounting end face; the placement opening is used for allowing the electronic device to be put into the accommodating space; the protector is arranged on the second mounting end face; and the protector blocks the mounting opening, so that the protector is fitted to a screen of the electronic device in the accommodating space via the mounting opening.

2. The protector installation device according to claim 1, wherein the protector comprises a first unit protector and a second unit protector which are stacked; the first unit protector is connected to the second mounting end face; the second unit protector is stacked on one side of the first unit protector facing to the mounting opening; and the second unit protector falls into the mounting opening.

3. The protector installation device according to claim 2, wherein an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; and the upper positioning hole sleeves the upper positioning block, and the lower positioning hole sleeves the lower positioning block, so that the first unit protector is connected to the second mounting end face.

4. The protector installation device according to claim 3, wherein the shell further comprises a fixing member; the fixing member is provided with a limiting slot for plugging the upper positioning block; and the upper positioning block threaded into the upper positioning hole is plugged into the limiting slot, so that the upper edge portion is fixed between the second mounting end face and the fixing member.

5. The protector installation device according to claim 2, wherein the protector further comprises a third unit protector; the third unit protector is stacked on one side of the second unit protector facing to the mounting opening; and the third unit protector falls into the mounting opening.

6. The protector installation device according to claim 5, wherein a lift-up portion extends out of a top of the third unit protector; the mounting opening is provided with an accommodating slot used for accommodating the lift-up portion; and the lift-up portion is arranged in the accommodating slot when the protector blocks the mounting opening.

7. A protector installation method for an electronic device, comprising the following steps:
providing the protector installation device for an electronic device according to claim 1, wherein the protector comprises a first unit protector and a second unit protector which are stacked; the first unit protector is connected to the second mounting end face; the second unit protector is stacked on one side of the first unit protector facing to the mounting opening; the second unit protector falls into the mounting opening;
enabling a screen of the electronic device to face to the second unit protector at the second mounting end face, and putting the electronic device into the accommodating space via the placement opening;
applying an acting force, which faces to the screen of the electronic device, to the bottom of the first unit protector from a side where the second mounting end face is located, so as to attach the bottom of the second unit protector to the screen of the electronic device;
lifting the first unit protector off the second unit protector from the bottom of the first unit protector; and when the first unit protector is lifted off the second unit protector, applying, by the bent first unit protector, an acting force, which faces to the screen of the electronic device, to the second unit protector, so as to discharge air between the second unit protector and the screen of the electronic device and attach the second unit protector to the screen of the electronic device.

8. The protector installation method according to claim 7, wherein
the protector further comprises a third unit protector; the third unit protector is stacked on one side of the second unit protector facing to the mounting opening; the third unit protector falls into the mounting opening; a lift-up portion extends out of a top of the third unit protector; the mounting opening is provided with an accommodating slot used for accommodating the lift-up portion; the lift-up portion is arranged in the accommodating slot when the protector blocks the mounting opening;
the step of enabling a screen of the electronic device to face to the second unit protector at the second mounting end face, and putting the electronic device into the accommodating space via the placement opening comprises:
lifting the third unit protector off the second unit protector through the lift-up portion; and
putting the electronic device into the accommodating space.

9. The protector installation method according to claim 8, wherein
the step of applying an acting force, which faces to the screen of the electronic device, to the bottom of the first unit protector from a side where the second mounting end face is located, so as to attach the bottom of the second unit protector to the screen of the electronic device comprises:
applying the acting force, which faces to the screen of the electronic device, to the bottom of the first unit protector from one side to the other side; and
discharging the air between the bottom of the second unit protector and the screen of the electronic device, so as to cling the bottom of the second unit protector to the bottom of the screen of the electronic device.

10. The protector installation method according to claim 9, wherein
an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; the upper positioning hole sleeves the upper positioning block, and the lower positioning hole sleeves the lower positioning block, so that the first unit protector is connected to the second mounting end face; the shell further comprises a fixing member; the fixing member is provided with a limiting slot for plugging the upper positioning block; the upper positioning block threaded into the upper positioning hole is plugged into the limiting slot, so that the upper edge portion is fixed between the second mounting end face and the fixing member;
the step of lifting the first unit protector off the second unit protector from the bottom of the first unit protector; and when the first unit protector is lifted off the second unit protector, applying, by the bent first unit protector, an acting force, which faces to the screen of the electronic device, to the second unit protector, so as to discharge air between the second unit protector and the screen of the electronic device and attach the second unit protector to the screen of the electronic device comprises:
grabbing the lower edge portion on the side where the second mounting end face is located;
lifting the first unit protector off the second unit protector from the bottom to the top through the lower edge portion;
bending the lifted first unit protector relative to the non-lifted first unit protector to apply the acting force, which faces to the screen of the electronic device, to the second unit protector; and
when the first unit protector is lifted off the second unit protector from the bottom to the top, under the acting force of the first unit protector, discharging the air between the second unit protector and the screen of the electronic device from bottom to top, so as to attach the second unit protector to the screen of the electronic device.

11. A protector installation device for an electronic device, comprising a shell and a transparent protection film, the shell comprising an accommodating space, a placement opening communicated with the accommodating space, and a mounting opening communicated with the accommodating space and facing the placement opening, the placement opening configured for allowing the electronic device to be put into the accommodating space, the transparent protection film disposed at the mounting opening, so that the transparent protection film is able to be attached to a screen of the electronic device in the accommodating space via the mounting opening.

12. The protector installation device according to claim 11, wherein the shell comprises a first mounting end face having the placement opening and a second mounting end face having the second mounting end face; the transparent protection film comprises a first unit protector and a second unit protector which are stacked; the first unit protector is connected to the second mounting end face; the second unit protector is stacked on one side of the first unit protector facing to the mounting opening; and the second unit protector falls into the mounting opening.

13. The protector installation device according to claim 12, wherein an upper edge portion and a lower edge portion respectively extend out of a top and bottom of the first unit protector; the upper edge portion is provided with an upper positioning hole; the lower edge portion is provided with a lower positioning hole; a top and bottom of the second mounting end face are respectively provided with an upper positioning block and a lower positioning block; and the upper positioning hole sleeves the upper positioning block, and the lower positioning hole sleeves the lower positioning block, so that the first unit protector is connected to the second mounting end face.

14. The protector installation device according to claim 13, wherein the shell further comprises a fixing member; the fixing member is provided with a limiting slot for plugging the upper positioning block; and the upper positioning block threaded into the upper positioning hole is plugged into the limiting slot, so that the upper edge portion is fixed between the second mounting end face and the fixing member.

15. The protector installation device according to claim 12, wherein the transparent protection film further comprises a third unit protector; the third unit protector is stacked on one side of the second unit protector facing to the mounting opening; and the third unit protector falls into the mounting opening.

16. The protector installation device according to claim 15, wherein a lift-up portion extends out of a top of the third unit protector; the mounting opening is provided with an accommodating slot used for accommodating the lift-up portion; and the lift-up portion is arranged in the accommodating slot when the transparent protection film blocks the mounting opening.
